(19) United States
(12) Patent Application Publication
(10) Pub. No.: US 2025/0274128 A1
(43) Pub. Date: Aug. 28, 2025

(54) MIXED SIGNAL ELECTRONICS FOR LOCKING CONTROL OF HIGH-Q FEEDBACK LOOPS AND ASSOCIATED CIRCUITRY FOR DETECTING PHASE SHIFT OF A RESONATOR

(71) Applicant: Panasonic Corporation of North America, Newark, NJ (US)

(72) Inventors: Mohammad Maymandi Nejad, Waltham, MA (US); Chechuan Che, Waltham, MA (US); Yaesuk Jeong, Waltham, MA (US)

(21) Appl. No.: 19/091,053

(22) Filed: Mar. 26, 2025

Related U.S. Application Data
(63) Continuation-in-part of application No. 19/061,391, filed on Feb. 24, 2025.
(60) Provisional application No. 63/556,998, filed on Feb. 23, 2024.

(51) Int. Cl. H03L 7/081; H03L 1/02; H03L 7/095

(52) U.S. Cl. CPC H03L 7/081; H03L 1/02; H03L 7/095

(57) ABSTRACT

Circuits for controlling the output of a frequency resonator, specifically for adjusting the output based upon changes in operational parameters such as changes in temperature, are provided. For example, a circuit can include a time-to-digital convertor (TDC) loop configured to be locked to a reference signal and a lock range control (LRC) circuit operably coupled to the TDC loop, the LRC circuit including a sensor and a limiter. The limiter is configured to provide LRC input signal to divider circuitry such that an output of the TDC loop stays close to a resonant value of the reference signal. An alternate circuit can include an integrator circuit path to generate an output signal having an output frequency and a delay loop configured to adjust a reference signal frequency, the delay loop including a delay element configured to offset a phase of the reference signal based upon an initial calibration.

### CROSS REFERENCE TO RELATED APPLICATIONS

This application is a continuation-in-part of U.S. application Ser. No. 19/061,391, filed on Feb. 24, 2025, titled “MIXED SIGNAL ELECTRONICS FOR LOCKING CONTROL OF HIGH-Q FEEDBACK LOOPS AND ASSOCIATED CIRCUITRY FOR DETECTING PHASE SHIFT OF A RESONATOR,” which claims priority to U.S. Provisional Application Ser. No. 63/556,998, filed on Feb. 23, 2024, titled “MIXED SIGNAL ELECTRONICS FOR LOCKING CONTROL OF HIGH-Q FEEDBACK LOOPS AND ASSOCIATED CIRCUITRY FOR DETECTING PHASE SHIFT OF A RESONATOR.” These documents are herein incorporated by reference in their entireties.

### BACKGROUND

High-Q systems are those with a high Q-factor which, in physics, indicates a system's ability to store energy relative to the energy it dissipates over a single oscillation cycle. Thus, essentially, a high-Q system can resonate at a specific frequency for an extended time period with minimal energy loss.

Feedback loops can be used for high-precision timing circuits that result in the locking of two high-Q systems when sharing a common reference timing signal. However, changes in operational conditions can cause various components within timing circuits to perform at changing frequencies, resulting in the two high-Q systems falling out of synchronization.

The present disclosure relates to the field of feedback loops and associated circuitry for maintaining resonant frequency in a feedback loop to produce a constant clock signal.

### BRIEF SUMMARY

In at least one example as described herein, a circuit for controlling the output of a frequency resonator is provided. The circuit includes a time-to-digital convertor (TDC) loop configured to be locked to a reference signal. The circuit further includes a lock range control (LRC) circuit operably coupled to the TDC loop, the LRC circuit including a sensor and a limiter, wherein the limiter is configured to provide LRC input signal to signal divider circuitry such that an output of the TDC loop stays close to a resonant value of the reference signal.

Implementations of the circuit for controlling the output of a frequency resonator can include one or more of the following features.

In some examples of the circuit for controlling the output of a frequency resonator, the LRC input signal can include a temperature-dependent signal. In some further examples, the sensor includes a temperature sensor. In some further examples, the LRC circuit includes a conditioning circuit to filter the output of the temperature sensor; and an analog to digital converter to convert an output of the conditioning circuit to a digital signal for processing by the signal divider circuitry.

In some examples of the circuit for controlling the output of a frequency resonator, the limiter is configured to operate at a frequency range such that an output of the limiter is within an acceptable input range of the signal divider circuitry.

In some examples of the circuit for controlling the output of a frequency resonator, the circuit includes a high-Q circuit configured to resonate at a specific frequency with minimal energy loss over time.

In at least one example as describe herein, a circuit for adjusting signal frequency based upon changes in operational parameters is provided. The circuit includes an integrator circuit path configured to generate an output signal having an output frequency. The circuit further includes a delay locked loop configured to adjust a reference signal frequency, the delay locked loop including a delay element that is configured to offset a phase of the reference signal based upon an initial calibration such that the reference signal frequency matches the output frequency of the output signal.

Implementations of the circuit for adjusting signal frequency based upon changes in operational parameters can include one or more of the following features.

In some examples of the circuit for adjusting signal frequency based upon changes in operational parameters, the integrator circuit path comprises buffering and filtering circuitry to remove any harmonics from the reference signal.

In some examples of the circuit for adjusting signal frequency based upon changes in operational parameters, the circuit is further configured to adjust signal frequency based upon changes in operational temperature. In some examples, the delay element is further configured to offset the phase of the reference signal based upon an initial temperature-based circuit calibration.

In some examples of the circuit for adjusting signal frequency based upon changes in operational parameters, the output signal of the integrator circuit path and the calibrated reference signal are combined to produce a switched current output signal.

In some examples of the circuit for adjusting signal frequency based upon changes in operational parameters, the circuit includes a high-Q circuit configured to resonate at a specific frequency with minimal energy loss over time.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and are incorporated in and constitute a part of this specification but are not intended as a definition of the limits of any particular example. The drawings, together with the remainder of the specification, serve to explain principles and operations of the described and claimed aspects. In the figures, each identical or nearly identical component that is illustrated in various figures is represented by a like numeral. For purposes of clarity, not every component may be labeled in every figure.

FIG. 1 illustrates an example phase locked loop, in accordance with at least one embodiment as described herein.

FIG. 2 illustrates an example architecture for a high-precision timing circuit, in accordance with at least one embodiment as described herein.

FIG. 3 illustrates an example architecture for a lock range control mechanism, in accordance with at least one embodiment as described herein.

FIG. 4 illustrates the operational range of a limiter for a lock range control mechanism, in accordance with at least one embodiment as described herein.

FIG. 5 illustrates a clock circuit including an integrator and delay locked loop, in accordance with at least one embodiment as described herein.

### DETAILED DESCRIPTION

The present disclosure is directed to generating timing and/or clock signals and maintaining resonant frequency during operation. Any potential changes in operational conditions can result in a change to the circuit's resonant frequency and, thus, a change to the overall output of the timing circuitry. For example, during operation, a change to the operational temperature of one or more components within the circuit may result in potential change to the overall output of the complete circuit due to the physical changes of the materials within the components from the change in temperature.

The systems, methods, and circuits as described herein are designed to accommodate for changes in operational conditions while maintaining high-Q levels of operation of timing circuits.

Examples of the systems, processes, and circuits discussed herein are not limited in application to the details of construction and the arrangement of components set forth in the following description or illustrated in the accompanying drawings. The methods and systems are capable of implementation in other examples and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

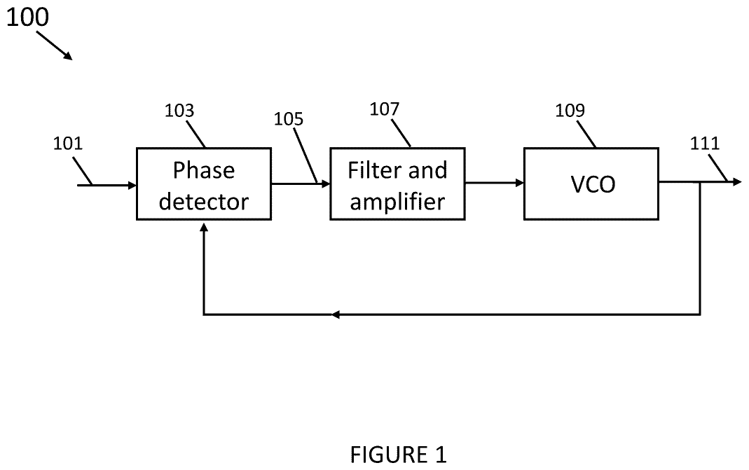

FIG. 1 illustrates a sample architecture of phase locked loops (PLLs). PLLs are feedback control systems that can produce an output signal linked to the phase of an input signal. PLLs can be used in clock generation and frequency synthesis circuits. The PLL 100 illustrated in FIG. 1 can include an input signal 101 (reference signal) into a phase detector 103, which is configured to determine the phase and/or frequency of the input signal 101 in relation to an output signal 111. A resultant error signal 105 can be filtered and subsequently amplified by the loop filter and amplifier 107. After filtering and amplification, the resultant error signal 105 can be used to control/regulate a voltage-controlled oscillator (VCO) 109, which is configured to generate a timing signal 111 (output signal) that is fed back to the phase detector 103. When the output frequency and phase are matched to the incoming frequency and phase of the phase detector 103, i.e., a steady-state, the PLL is considered locked. When the output frequency and phase are not matched to the incoming frequency and phase, the PLL is considered not locked (or unlocked).

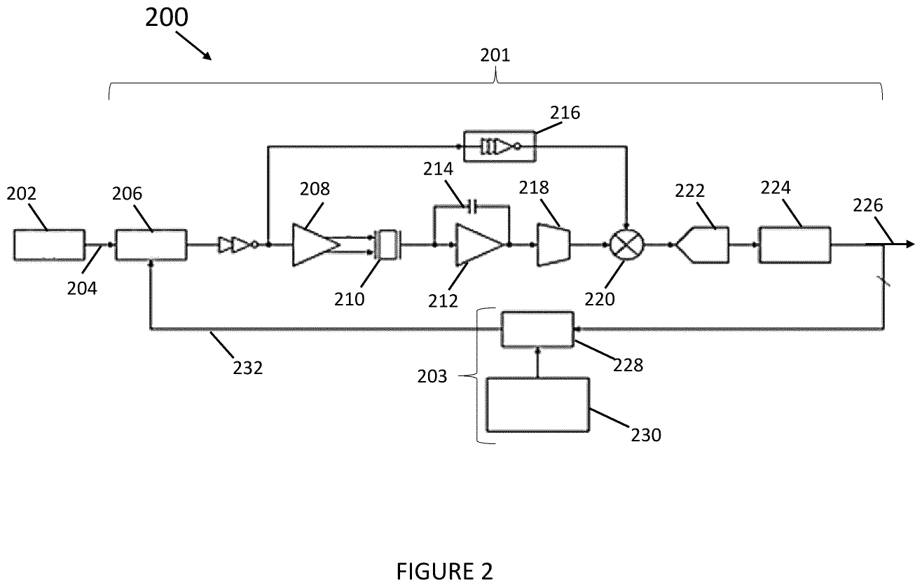

FIG. 2 illustrates a high precision timing circuit 200 that can use a PLL to regulate timing. Here, the high-precision timing circuit 200 can use a fractional-N PLL 206. In other embodiments, the high precision timing circuit 200 can use an integer-N PLL, or other types of PLLs. A fractional-N PLL can allow frequency resolution that is a fractional portion of the reference frequency. Fractional-N PLLs can improve phase noise, which can improve switching speed and loop bandwidth.

Additionally, as illustrated, the high precision timing circuit 200 include a reference oscillator 202 configured to generate a reference signal 204 such as a high-stability sine wave signal. The reference oscillator 202 can be a high-Q microelectromechanical system (MEMS) device. In some embodiments, the frequency of this reference oscillator 202 is based upon a high-Q (MEMS) device. During operation, the frequency of this oscillator 202 can change slightly with changes in temperature.

As further shown in FIG. 2, the reference signal 204 is applied to a time-to-digital converter (TDC) loop 201, which can include a fractional-N PLL 206, a buffer amplifier 208, another high-Q MEMS device 210, an integrator amplifier 212, an integrator capacitor 214, delay element 216, gm-cell 118, combiner/mixer 220, analog-to-digital converter 222, controller 224, and output (TDCₒᵤₜ) 226. These elements will further be described below. To operate properly, the TDC loop 201 is generally locked to the reference signal 104. Because the quality factors of the two MEMS devices 202, 210 are very high, any slight frequency shift in each of the two MEMS devices 202, 210 can cause the TDC loop 201 to become out of lock with the reference signal 204. If the reference signal 204 and the TDC loop 201 become unlocked, it can take time to return to the locked state again. Ultimately, there is also a chance that the lock condition will never be met.

To mitigate the chance the TDC loop 201 becomes unlocked with the reference signal 204, a lock range control (LRC) mechanism 203 can be used with the TDC loop 201. This LRC mechanism 203 can include a temperature sensor 228 and a limiter 230 configured to limit the input to the fractional-N PLL 206. The LRC mechanism 203 can output an output signal 232 into the fractional-N PLL 206.

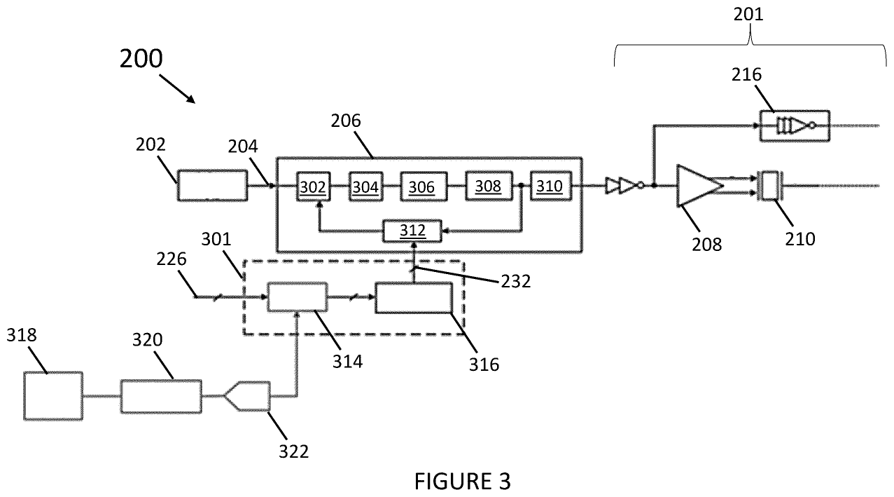

FIG. 3 shows the high precision timing circuit 200 with the fractional-N PLL 206 and LRC mechanism 203 in more detail. Particularly, the fractional-N PLL 206 can include a phase detector 302, a charge pump 304, a loop filter 306, a VCO 308, a N divider 310, and a divider 312.

In certain implementations during operation of the LRC mechanism 203, the TDC loop 201 is not locked to the reference signal 204 when the high precision timing circuit 200 is powered up because the output frequency of the fractional-N PLL 206 is not within the bandwidth of the TDC MEMS 210. Because the Q of the TDC MEMS 100 is very high, a slight frequency shift makes the output of the TDC MEMS 100 very small. Therefore, the loop gain may drop below 1 such that the TDC loop 201 does not settle and does not lock to the reference signal. Even if the loop gain is more than 1, it may take a long time for the TDC loop 201 to settle and lock to the reference signal.

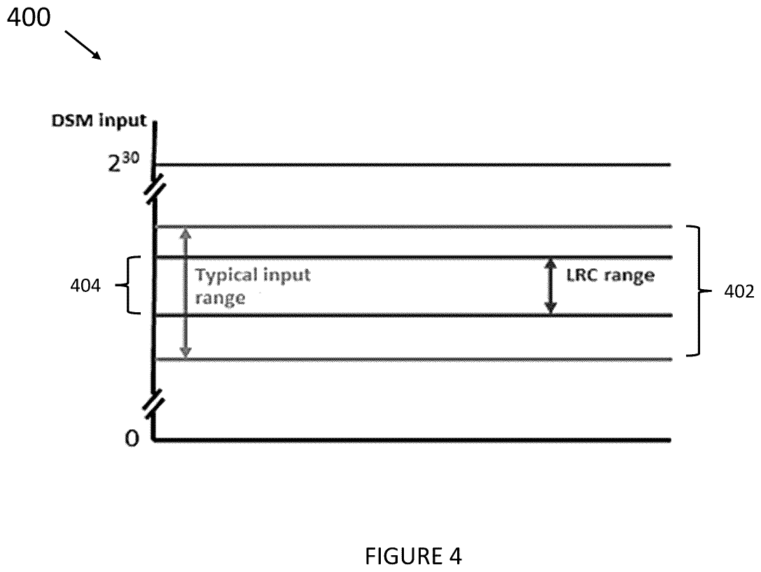

To avoid this, a digital signal processing circuit 301 including a limiter 314 and a dynamic saturation modeling (DSM) component 316 can be implemented in some implementations. Particularly, the limiter 314 can be used to limit the signal 232 going into the fractional-N PLL divider 312 (e.g., the sample limiter operational range as shown in FIG. 4 and described in more detail below). In this way, the frequency of the signal going into the TDC MEMS 210 stays close to it resonant value. This helps the TDC loop 201 to settle very fast after powering up or if the lock condition is lost during normal operation.

In certain embodiments, the two high and low thresholds of the limiter 314 can be temperature dependent. In these cases, a temperature sensor 318 can be used to measure and digitize the temperature of the TDC MEMS 210. The temperature sensor can be coupled to the limiter 314 using a signal conditioner 320 and analog-to-digital converter (ADC) 322. The temperature of the TDC MEMS 210 can be used to adjust characteristics of the limiter.

In one embodiment, the limiter 314 can be configured to apply a limiting mechanism that is processed in the digital domain, so that any correction can be applied digitally. For example, if there is any curvature in the characteristic of the TDC MEMS 210, it can be reduced by applying a polynomial curve fitting. In other embodiments, the limiter 314 can be an analog device. The output of the temperature sensor 318 can be converted to a digital signal using the ADC 322 for further processing. Prior to conversion, the output of the temperature sensor 318 can be conditioned by the signal conditioner 320 to, for example, filter the signal to remove noise or any other unwanted portions of the output of the temperature sensor. The conditioned signal can then be converted to a digital signal by ADC 322. The converted digital signal can then be passed to the limiter 314 for further processing in concert with the DSM 316.

Referring to FIG. 4, an example operational range graph 400 is shown for various circuit components as described herein. As specifically shown in FIG. 4, the input of the fractional-N PLL 206 can be configured for a specific range 402, and the output of the limiter (e.g., limiter 314) can be configured such that it has a specific range 404. As shown in FIG. 4, the range of the limiter 404 falls completely within range of the fractional-N PLL 402. As such, the output of the limiter 108 can be configured such that it is within the acceptable input range of the fractional-N PLL 206.

As described herein, when circuitry temperature changes, the resonant frequency of a resonator shifts. By driving the resonator with a clock centered at its resonant frequency, the resonant frequency change incurs a phase change corresponding to temperature changes. In certain implementations, this phase change can be detected by mixing the driven clock with the electronic current that flows out of the resonator after it is processed through an electronic integrator. The integrator is converted to current via a gm cell, and the current is switched by the driven clock. The DC component of the mixing represents the phase change.

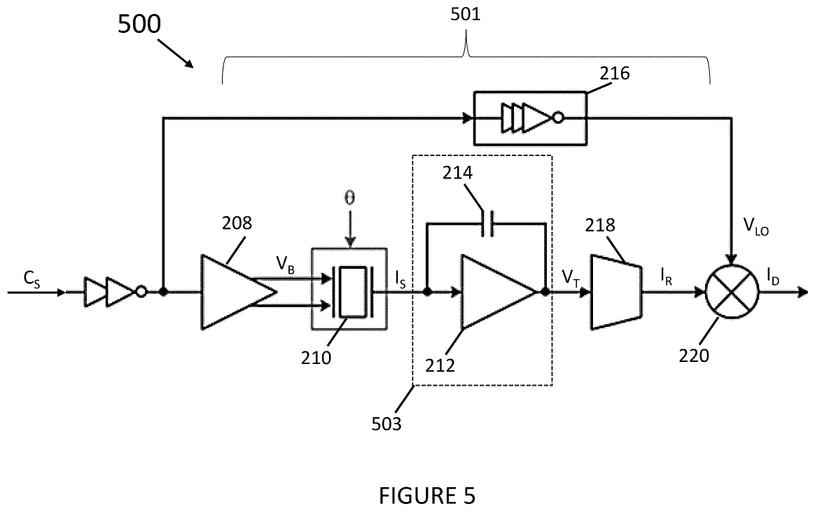

Referring to FIG. 5, another method of adjusting signal frequency is shown based upon changes in operational parameters, including using an integrator and delay locked loop. For example, as illustrated in FIG. 5, the TDC loop 201 can include an integrator 503 and a delay locked loop 501 for adjusting frequency based upon operational temperature. In the circuit as shown in FIG. 5, a clock signal C_{S} can be input to the MEMS 510 via a buffer amplifier 208. The clock signal C_{S} can be locked to the resonant frequency of MEMS 210 at, for example, 41 MHz. This clock signal C_{S} can be buffered by a high-bandwidth open-loop amplifier 208 and configured to drive MEMS 210. MEMS 210, being a high-Q device with limited bandwidth, can filter out the harmonics of the clock signal C_{S}. MEMS 210 can output current signal I_{S}, which can be a sinusoidal signal.

In certain implementations, when the operational temperature of the high precision timing circuit 200 or any individual circuit component varies, the resonant frequency of MEMS 210 shifts accordingly. This shift of resonant frequency causes current I_{S} to move out of phase with respect to voltage V_{B}. In certain implementations, the phase of current I_{S} shifts by 90° after passing through the integrator 503. In such embodiments, the integrator 503 can include capacitor 214 and amplifier 212. The voltage signal V_{T} can then be converted to current I_{R} via a gm-cell.

In some examples, V_{LO} is a square-wave clock running at input clock signal C_{S} rate. The following equation shows the relationship assuming V_{LO} is sinusoidal signal with amplitude of V_{A}. The simplification is valid since the harmonics of mixing of V_{LO} and I_{R} will be filtered out before the ADC converter 222:

$${V}_{A} \cdot sin ( ω t ) \times {i}_{r} \cdot cos ( ω t + θ ) = \frac{1}{2} {V}_{A} \cdot {i}_{r} [ sin ( 2 ω t + θ ) - sin ( θ ) ]$$

This equation represents the front-end gain of the phase detector 302, which is high based on the Q of the resonator. Switch current I_{D} can then be filtered and digitally converted in baseband to obtain the phase information.

Because the high precision timing circuit 200 is processing relatively high-frequency signals, the delay through the various sense path blocks can become temperature dependent. This issue can be alleviated by having a delay element 216 that can be calibrated to help ensure that the systematic phase offset between I_{R} and V_{LO} are set properly during a temperature-controlled initial calibration.

Another implementation of the delay element 216 is via a DLL (Delay-locked-loop) such that V_{LO} does not vary with respect to input clock signal C_{S}. In addition, the circuit can be automatically calibrated via a proportional to absolute temperature (PTAT) based DLL in the delay element to further alleviate the temperature dependence of difference in phase between the input signal 204 and the output signal 226. The nonlinearity of the sensing path phase delay with respect to temperature is dominated by MEMS 210 linearity instead of the circuit linearity.

It should be noted that temperature-dependent calibration and resonant frequency adjustment as described above is provided by way of example only. In certain implementations, changes to additional operational parameters of the circuitry and the individual circuitry components can be measured and accounted for. For example, additional changes in environmental parameters such as changes in humidity may be measured and accounted for. Similarly, physical operation parameters such as operational vibration or other movements of the circuitry and related components can be measured for calibration and adjustment during operation.

Having thus described several aspects of at least one example, it is to be appreciated that various alterations, modifications, and improvements will readily occur to those skilled in the art. For instance, examples disclosed herein can also be used in other contexts. Such alterations, modifications, and improvements are intended to be part of this disclosure and are intended to be within the scope of the examples discussed herein. Accordingly, the foregoing description and drawings are by way of example only.

Also, the phraseology and terminology used herein is for the purpose of description and should not be regarded as limiting. Any references to examples, components, elements or acts of the systems and methods herein referred to in the singular can also embrace examples including a plurality, and any references in plural to any example, component, element or act herein can also embrace examples including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” can be construed as inclusive so that any terms described using “or” can indicate any of a single, more than one, and all of the described terms. In addition, in the event of inconsistent usages of terms between this document and documents incorporated herein by reference, the term usage in the incorporated references is supplementary to that of this document; for irreconcilable inconsistencies, the term usage in this document controls.

What we claim is:

1. A circuit for controlling the output of a frequency resonator, the circuit comprising:
a time-to-digital convertor (TDC) loop configured to be locked to a reference signal; and
a lock range control (LRC) circuit coupled to the TDC loop and configured to provide a signal to the TDC loop, wherein the signal is configured to adjust an output signal of the TDC loop.

2. The circuit of claim 1, wherein the LRC input signal comprises a temperature-dependent signal.

3. The circuit of claim 2, wherein the sensor comprises a temperature sensor.

4. The circuit of claim 3, wherein the LRC circuit further comprises:
a conditioning circuit to filter the output of the temperature sensor; and
an analog to digital converter to convert an output of the conditioning circuit to a digital signal for processing by the signal divider circuitry.

5. The circuit of claim 1, wherein the limiter is configured to operate at a frequency range such that an output of the limiter is within an acceptable input range of the signal divider circuitry.

6. The circuit of claim 1, wherein the circuit comprises a high-Q circuit configured to resonate at a specific frequency with minimal energy loss over time.

7. A circuit for adjusting signal frequency based upon changes in operational parameters, the circuit comprising:
an integrator circuit configured to generate an output signal having an output frequency; and
a delay locked loop configured to offset a phase of the reference signal based upon an initial calibration such that the reference signal frequency matches the output frequency of the output signal.

8. The circuit of claim 7, wherein the integrator circuit comprises a buffering amplifier and a filter configured to remove harmonics from the reference signal.

9. The circuit of claim 7, wherein the integrator circuit is further configured to adjust signal frequency based upon changes in operational temperature.

10. The circuit of claim 9,
wherein the delay locked loop comprises a delay element, and
wherein the delay element is configured to offset the phase of the reference signal based upon an initial temperature-based circuit calibration.

11. The circuit of claim 7, wherein the output signal of the integrator circuit path and the calibrated reference signal are combined to produce a switched current output signal.

12. The circuit of claim 7, wherein the integrator circuit comprises a high-Q circuit configured to resonate at a specific frequency with minimal energy loss over time.

13. The circuit of claim 7, wherein the integrator circuit comprises a high-Q MEMS device configured to resonate at a specific frequency with minimal energy loss over time.
